(19) United States
(12) Patent Application Publication
(10) Pub. No.: US 2011/0037101 A1
(43) Pub. Date: Feb. 17, 2011

(54) SEMICONDUCTOR DEVICE

(76) Inventors: Kazushi Nakazawa, Toyama (JP); Toshiyuki Takizawa, Kyoto (JP); Tetsuzo Ueda, Osaka (JP); Daisuke Ueda, Kyoto (JP)

Correspondence Address: MCDERMOTT WILL & EMERY LLP, 600 13TH STREET, NW, WASHINGTON, DC, 20005-3096, US

(21) Appl. No.: 12/667,999

(22) PCT Filed: Mar. 27, 2009
(86) PCT No.: PCT/JP2009/001417

§ 371 Date: Jan. 6, 2010

(30) Foreign Application Priority Data
Jun. 5, 2008 (JP) 2008-148019

(51) Int. Cl. H01L 29/205; H01L 29/80; H01L 29/737; H01L 29/20

(52) U.S. Cl. 257/192; 257/201; 257/197; 257/615; 257/E29.091; 257/E29.315; 257/E29.188; 257/E29.089

(57) ABSTRACT

A semiconductor device includes an undoped GaN layer (13), an undoped AlGaN layer (14), and a p-type GaN layer (15). In the p-type GaN layer (15), highly resistive regions (15a) are selectively formed. Resistance of the highly resistive regions (15a) can be increased by introducing a transition metal, for example, titanium.

### TECHNICAL FIELD

The present invention relates to semiconductor devices applicable to, for example, power transistors or high-frequency transistors, particularly to semiconductor devices made of Group III nitride semiconductors.

### BACKGROUND ART

Group III nitride compound semiconductors (hereinafter also referred to simply as “nitride semiconductors”) represented by gallium nitride (GaN) have more excellent physical properties such as wider band gaps, higher breakdown field, and higher saturation velocity than silicon (Si) and gallium arsenide (GaAs), and are expected as new materials used for high-output transistors or high-frequency transistors. Furthermore, a band gap of a Group III nitride compound semiconductor can be freely changed by changing a mixed crystal ratio. For example, in an AlGaN/GaN hetero structure, in which AlGaN and GaN being nitride semiconductor layers having different band gaps are joined, a charge is generated at the heterojunction on a (0001) plane of a crystal structure due to spontaneous polarization and piezo-polarization, and a sheet carrier density of 1×10¹³ cm⁻² or more can be obtained even when the layers are undoped. Thus, a heterojunction field effect transistor (HFET) made of a nitride semiconductor utilizing the charge generated at the heterojunction as a channel can achieve a high current density to provide higher output power, and thus has been actively researched and developed.

When manufacturing an HFET, a conductive region in which a current flows, and a highly resistive region in which no current flows need to be selectively formed. In a nitride semiconductor, it is technically difficult to selectively grow a nitride semiconductor layer having a desired conductivity type or conductive properties. It is also difficult to selectively form a conductive region in a high resistive nitride semiconductor layer by ion implantation, since implanted impurities are not activated. Thus, selectively forming a highly resistive region in a conductive nitride semiconductor layer is a conventional method. That is, by ion-implanting impurities such as boron (B) and nitrogen (N) into a conductive nitride semiconductor layer, a highly resistive region is selectively formed in the nitride semiconductor layer (see, for example, Patent Document 1). To be specific, an energy level caused by defects occurring in the ion implantation is formed in a band gap of the nitride semiconductor to trap carriers, thereby increasing resistance of the nitride semiconductor layer.

### Citation List

### Patent Document

PATENT DOCUMENT 1: Japanese Patent Publication No. H11-214800

PATENT DOCUMENT 2: Japanese Patent No. 2661146

PATENT DOCUMENT 3: Japanese Patent Publication No. H10-154831

### SUMMARY OF THE INVENTION

### Technical Problem

However, in the above-described method of manufacturing the conventional semiconductor device, a defective band traps carriers to increase resistance. Thus, there is a problem that defects are recovered to decrease the resistance, particularly when a heat treatment at a high temperature of 800° C. or more is performed.

Furthermore, in ion implantation, an energy level, which is formed in a band gap of a nitride semiconductor to trap carriers, cannot be controlled. Thus, in a nitride semiconductor transistor, which includes an n-type nitride semiconductor layer and a p-type nitride semiconductor layer, when impurity elements are introduced into both of the semiconductor layers, it is impossible to selectively increase resistance of only one of the layers.

In view of the above-described conventional problem, a first objective of the present invention is to form a highly resistive region, which is stable to withstand high-temperature heat treatment, in a semiconductor device made of a Group III nitride semiconductor. A second objective is to selectively increase resistance of only one of an n-type semiconductor layer and a p-type semiconductor layer.

### Solution to the Problem

In order to achieve the above-described objective, a first semiconductor device according to the present invention includes a first semiconductor layer made of a first nitride semiconductor; and a second semiconductor layer made of a second nitride semiconductor. The first semiconductor layer includes a first region, into which a transition metal is introduced. The second semiconductor layer includes a second region, into which the transition metal is introduced. Resistance of only one of the first region and the second region is increased.

According to the first semiconductor device, in a semiconductor device including a nitride semiconductor layer, only by introducing at least one type of transition metal, resistance of a semiconductor layer of only one of conductivity types can be selectively increased.

In the first semiconductor device, the first semiconductor layer except for the first region has n-type conductivity. It is preferable that electrons are trapped by an energy level, which is formed in a band gap of the first nitride semiconductor by the transition metal, thereby increasing resistance of the first region.

Furthermore, in the first semiconductor device, the first semiconductor layer except for the first region has p-type conductivity. It is preferable that holes are trapped by an energy level, which is formed in a band gap of the first nitride semiconductor by the transition metal, thereby increasing resistance of the first region.

When the first semiconductor layer except for the first region has the n-type conductivity, copper can be used as the transition metal for trapping the electrons.

Furthermore, when the first semiconductor layer except for the first region has the p-type conductivity, titanium can be used as the transition metal for trapping the holes.

Moreover, the first semiconductor layer except for the first region has the n-type conductivity or the p-type conductivity, ruthenium can be used as the transition metal.

A second semiconductor device according to the present invention includes a substrate; a nitride semiconductor layer provided on the substrate; a source electrode and a drain electrode electrically coupled to the nitride semiconductor layer; and a gate electrode provided on the nitride semiconductor layer to be positioned between the source electrode and the drain electrode. The nitride semiconductor layer includes a highly resistive region, into which a transition metal is introduced.

In the second semiconductor device, the nitride semiconductor layer includes a nitride semiconductor layer doped with impurities providing p-type conductivity. The highly resistive region is preferably formed to exclude at least a part directly under the gate electrode in the nitride semiconductor layer, into which the impurities providing p-type conductivity are introduced.

Furthermore, in the second semiconductor device, the highly resistive region is preferably formed under the gate electrode in the nitride semiconductor layer to be in contact with the gate electrode.

Moreover, in the second semiconductor device, the nitride semiconductor layer includes a channel region which is a channel of a current flowing between the source electrode and the drain electrode. The highly resistive region is preferably formed under the channel region.

A third semiconductor device according to the present invention includes a substrate; a first nitride semiconductor layer provided on the substrate, and into which impurities providing a first conductivity type are introduced; a second nitride semiconductor layer provided on and in contact with an upper surface of the first nitride semiconductor layer, and into which impurities providing a second conductivity type are introduced; a third nitride semiconductor layer provided on and in contact with an upper surface of the second nitride semiconductor layer, and into which impurities providing the first conductivity type are introduced; a collector electrode electrically coupled to the first nitride semiconductor layer; a base electrode electrically coupled to the second nitride semiconductor layer; and an emitter electrode electrically coupled to the third nitride semiconductor layer. The first nitride semiconductor layer includes a highly resistive region, into which a transition metal is introduced.

In the second or third semiconductor device, the highly resistive region is preferably an isolation region located at a periphery of an active region of the semiconductor device.

A fourth semiconductor device according to the present invention includes a nitride semiconductor layer; and a highly resistive region formed in the nitride semiconductor layer. Into the highly resistive region, a transition metal and another element as impurities are introduced.

A fifth semiconductor device according to the present invention includes a nitride semiconductor layer; and a highly resistive region formed in the nitride semiconductor layer, and into which a transition metal is introduced. At least one of the highly resistive region and a region adjacent to the highly resistive region includes fluorine interstitial in a lattice structure.

### ADVANTAGES OF THE INVENTION

In the semiconductor device according to the present invention, a highly resistive region can be formed, which is stable to withstand high-temperature heat treatment. Furthermore, resistance of only one of an n-type semiconductor layer and a p-type semiconductor layer can be selectively increased. Due to these advantages, a nitride semiconductor device including a highly resistive region which is stable even after a high-temperature heat treatment, a normally-off type nitride semiconductor device in which no current collapse occurs, and a nitride semiconductor device achieving a high maximum oscillation frequency can be obtained.

### BRIEF DESCRIPTION OF THE DRAWINGS

FIG. 1 is a schematic cross-sectional view illustrating a semiconductor device according to a first embodiment of the present invention.

FIGS. 2A and 2B illustrate electronic states formed when transition metals are introduced into a nitride semiconductor. FIG. 2A is a graph illustrating 3d transition metals, and FIG. 2B is a graph illustrating 4d transition metals.

FIG. 3 illustrates static characteristics of a transistor when a bias voltage is applied as a DC voltage and as a pulse voltage to the semiconductor device according to the first embodiment of the present invention.

FIG. 4 is a schematic cross-sectional view illustrating a semiconductor device according to a modification of the first embodiment of the present invention.

FIG. 5 is a schematic cross-sectional view illustrating a semiconductor device according to a second embodiment of the present invention.

FIG. 6 is a schematic cross-sectional view illustrating a semiconductor device according to a third embodiment of the present invention.

FIG. 7 is a schematic cross-sectional view illustrating a semiconductor device according to a fourth embodiment of the present invention.

FIG. 8 is a schematic cross-sectional view illustrating a semiconductor device according to a fifth embodiment of the present invention.

FIG. 9 is a graph illustrating electronic states formed when an interstitial transition metal and/or an interstitial fluorinate are/is introduced into a nitride semiconductor.

FIG. 10 is a schematic cross-sectional view illustrating a semiconductor device according to a modification of the fifth embodiment.

### DESCRIPTION OF REFERENCE CHARACTERS

11 Substrate
12 Buffer Layer
13 GaN Layer
14 AlGaN Layer
15 P-Type GaN Layer
15a Highly Resistive Regions
16 Gate Electrode
17 Source Electrode
18 Drain Electrode
19 Transition-Metal-Doped Regions
20 Isolation Regions
21 Substrate
22 Buffer Layer
23 GaN Layer
24 AlGaN Layer
24a Highly Resistive Region
25 Gate Electrode
26 Source Electrode
27 Drain Electrode
28 Isolation Regions
31 Substrate
32 Buffer Layer
33 Highly Resistive Layer
34 GaN Layer
35 AlGaN Layer
36 Gate Electrode
37 Source Electrode
38 Drain Electrode
39 Isolation Regions
41 Substrate
42 Buffer Layer
43 Collector Layer
43a Highly Resistive Regions
44 Base Layer
44b Non-Highly Resistive Regions
45 Emitter Layer
46 Collector Electrode
47 Base Electrode
48 Emitter Electrode
49 Isolation Regions
51 Substrate
52 Buffer Layer
53 GaN Layer
54 AlGaN Layer
55 Fluorine Doped GaN Layer
55a Highly Resistive Regions
56 Gate Electrode
57 Source Electrode
58 Drain Electrode
59 Transition-Metal-Doped Regions
60 Isolation Regions

### DESCRIPTION OF EMBODIMENTS

### First Embodiment

A first embodiment of the present invention will be described hereinafter with reference to the drawings.

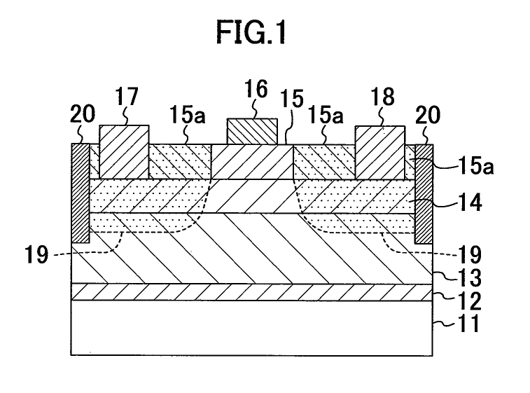

FIG. 1 illustrates a semiconductor device according to the first embodiment of the present invention, and a cross-sectional structure of a heterojunction field effect transistor (HFET) made of a Group III nitride semiconductor.

As shown in FIG. 1, in the HFET according to the first embodiment, on a main surface of a substrate 11 made of, for example, sapphire (single crystal Al₂O₃), a buffer layer 12 having thickness of 100 nm and made of aluminum nitride (AlN), an undoped GaN layer (a channel formation layer) 13 having thickness of 2 μm, an undoped AlGaN layer (a carrier supply layer) 14 having thickness of 25 nm, and a p-type GaN layer 15 having thickness of 100 nm and doped with magnesium (Mg) are formed one on another by epitaxial growth. The term “undoped” as used here means that a dopant providing a conductivity type is intentionally not introduced during a crystal growth.

On the p-type GaN layer 15, a gate electrode 16 made of palladium (Pd) is formed in contact with the p-type GaN layer 15. In regions of the p-type GaN layer 15 except for at least a part directly under the gate electrode 16, highly resistive regions 15a with increased resistance are formed by introducing a transition metal, titanium (Ti).

In regions on the AlGaN layer 14, which are on both sides of the p-type GaN layer 15 and in which the highly resistive regions 15a are etched, a source electrode 17 and a drain electrode 18, each of which is a multilayer of titanium (Ti) and aluminum (Al), are formed in contact with the AlGaN layer 14. Note that the source electrode 17 and the drain electrode 18 may be in contact with the AlGaN layer 14 only, with the underlying GaN layer 13 only, or with both of the GaN layer 13 and the AlGaN layer 14.

Furthermore, in regions outside the source electrode 17 and the drain electrode 18, isolation regions 20 are formed, into which boron (B) and a transition metal, e.g., titanium (Ti) or ruthenium (Ru), are introduced to increase the resistance.

As a feature of the first embodiment, as shown in FIG. 1, Ti for forming the highly resistive regions 15a is introduced to reach the AlGaN layer 14 under the p-type GaN layer 15 and further upper portions of the underlying GaN layer 13 to form transition-metal-doped regions 19. However, as will be described later, since Ti increases resistance of a p-type nitride semiconductor layer only, the highly resistive regions 15a are formed only in the p-type GaN layer 15 in this embodiment.

As such, in the region under the gate electrode 16 of a nitride semiconductor transistor provided with a p-type nitride semiconductor layer (the p-type GaN layer 15) between the gate electrode 16 and the carrier supply layer (the AlGaN layer 14), a channel region, which is formed at a heterojunction interface of AlGaN/GaN under the gate electrode 16, has a higher energy level than the Fermi level. This enables depletion of the channel region located in a portion under the gate electrode 16. This allows a so-called normally-off operation, in which no drain current flows when no gate voltage is applied, without reducing the maximum drain current.

Such an HFET is conventionally formed by removing both side portions of the gate electrode 16 on the p-type GaN layer 15 by dry etching. Due to the dry etching, a trap level is formed on a surface of the undoped AlGaN layer 14. The trap level formed on the surface traps electrons during a high-power and high-speed switching operation to cause a so-called current collapse, i.e., phenomenon in which a drain current decreases.

However, in the first embodiment, no dry etching is performed to both side portions of the gate electrode 16 on the p-type GaN layer 15. A transition metal such as titanium (Ti), which forms an energy level for trapping only holes, is selectively introduced to increase resistance of the p-type GaN layer 15, thereby forming the highly resistive regions 15a. This enables a switching operation without trapping electrons existing in the channel region, and thus, achieves a normally-off type nitride semiconductor HFET, in which no current collapse occurs.

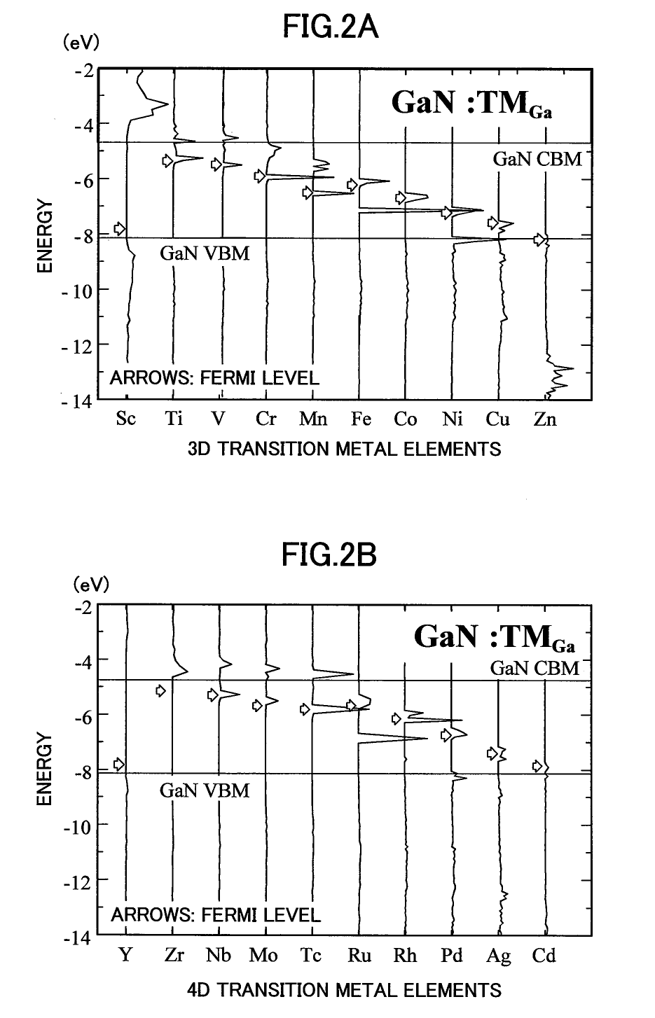

FIGS. 2A and 2B illustrate a result obtained by first principles band calculation with respect to impurity energy levels formed when transition metals are introduced into a nitride semiconductor. FIG. 2A illustrates a case where 3d transition metal elements are substituted for a Ga site, and FIG. 2B illustrates a case where 4d transition metal elements are substituted for a Ga site. Furthermore, the “GaN CBM” in the graphs represents energy at a lower edge of a conduction band of GaN, and the “GaN VBM” represents energy at the upper edge of a valence band of GaN. Moreover, the arrows in the graphs represent the Fermi levels. When a transition metal is introduced into a nitride semiconductor, localized impurity energy levels are formed in a band gap of the nitride semiconductor due to d-electrons which do not contribute to a chemical bond. Thus, when a transition metal is introduced into a conductive nitride semiconductor, impurity energy levels formed by the introduction of the transition metal trap carriers (majority carriers), thereby allowing an increase in resistance of the nitride semiconductor. This embodiment shows a result of the case where each transition metal is substituted for a Ga site. Since the d-electrons are not chemically bonded even when the transition metal is positioned interstitially within the lattice structure, impurity energy levels are formed in the band gap of the nitride semiconductor in a similar manner as shown in FIGS. 2A and 2B. Therefore, even when the transition metal is introduced into an interstitial site, the resistance of the nitride semiconductor can be increased.

Note that, the energy of these impurity energy levels differ from transition metal element to transition metal element. An impurity having an energy level for trapping electrons, is called an acceptor-type trap, an impurity having an energy level for trapping holes is called a donor-type trap. For example, by introducing a transition metal, which serves as a donor-type trap, into a p-type nitride semiconductor, the resistance can be increased. However, when the transition metal is introduced into an n-type nitride semiconductor, electrons are not trapped, and this does not change conductivity of the n-type nitride semiconductor. That is, even when any one transition metal serving as a donor-type trap or an acceptor-type trap is introduced into both of an n-type nitride semiconductor layer and a p-type nitride semiconductor layer, resistance of only one of the semiconductor layers can be increased.

Table 1 indicates a result of an experiment and a study of a change in sheet resistance when a transition metal, Ti is introduced into a nitride semiconductor.

TABLE 1

| Epitaxial | | Initial Sheet | Sheet Resistance after |
|---|---|---|---|
| Structure | Carrier | Resistance (Ω/sq.) | Ti Introduction (Ω/sq.) |
| p-GaN | Holes | 13000 | High Resistance |
| AlGaN/GaN | Carrier | 450 | 1700 |

In order to clarify effects of impurity energy levels formed in a band gap of the nitride semiconductor due to the Ti introduction, on electrons and holes; Ti is introduced into each of a wafer including an AlGaN/GaN layer having electrons as majority carriers, and a wafer including a p-type GaN layer having holes as majority carriers to measure the change in each sheet resistance in each of the cases.

As a result, when Ti is introduced into the p-type GaN layer, the sheet resistance became higher than a measurement limit value of the measuring system to allow the layer to be a semi-insulating layer. On the other hand, when Ti is introduced into the AlGaN/GaN layer, the sheet resistance merely approximately quadrupled. Note that, the term “high resistance” as used here means sheet resistance of 100 kΩ/sq. or more. Thus, it is found that Ti is a donor-type trap, since most of impurity energy levels, which are formed when Ti is introduced into the nitride semiconductor, trap holes.

In the first embodiment, it is necessary to increase the resistance of only the p-type GaN layer 15 doped with Mg and having holes as majority carriers, and not to affect electrons existing at the AlGaN/GaN interface between the underlying GaN layer 13 and AlGaN layer 14. Therefore, Ti is most appropriate as the transition metal. As long as a donor-type trap can be formed, other transition metals can also be used.

An example of manufacturing a Group III nitride semiconductor HFET having the above-described structure will be given below.

First, for example by metal organic chemical vapor deposition (MOCVD), on the main surface of the substrate 11 made of sapphire, the buffer layer 12 having thickness of 100 nm and made of AlN, the undoped GaN layer 13 having thickness of 2 μm, the undoped AlGaN layer 14 having thickness of 25 nm, and the p-type GaN layer 15 having thickness of 100 nm and doped with Mg are epitaxially grown one on another. For example, trimethyl gallium (TMG) and trimethyl aluminium (TMA) are used as a Group III source, and for example, ammonia (NH₃) is used as a nitrogen source. As a Mg source, which is a p-type dopant, bis(cyclopentadienyl)magnesium (Cp₂Mg) is used for example.

The material of the substrate 11 is not limited to sapphire, and may be silicon (Si), silicon carbide (SiC), gallium nitride (GaN), or the like. Furthermore, the impurities providing p-type conductivity in the p-type GaN layer 15 are not limited to Mg. The p-type GaN layer 15 may be made of Mg-doped AlGaN, or moreover may be made of Mg-doped AlGaN, of which the Al composition changes with respect to the thickness direction.

Next, in a gate electrode formation region on the epitaxially formed p-type GaN layer 15, a mask film (not shown) is formed, which covers the electrode formation region and is made of silicon oxide, for example. With the use of the formed mask film, Ti is selectively introduced into the p-type GaN layer 15. As a method of the Ti introduction, ion implantation, thermal diffusion, or the like can be used. In particular, thermal diffusion is preferable, since the nitride semiconductor layer is not damaged when Ti is introduced. The depth for introducing Ti into the nitride semiconductor layer may be the depth, at which all the regions of the p-type GaN layer 15 except for the region covered with the mask film become substantially the highly resistive regions 15a. Furthermore, as shown by the transition-metal-doped regions 19, the depth may reach the AlGaN layer 14 under the p-type GaN layer 15 or the GaN layer 13. This is because, as described above, impurity energy levels formed by Ti introduction trap holes but hardly affect electrons. Therefore, in the first embodiment, the depth for introducing Ti, may be, for example, 70 nm or more and 150 nm or less. Moreover, when Ti is introduced into an interstitial site of a crystal lattice, the number of d-electrons, which do not chemically bond, is two; the Ti concentration may be half or more of the concentration of holes in the p-type GaN layer 15, for example, about 1×10²⁰ cm⁻³. Note that the introduced transition metal is not limited to Ti, and may be a transition metal which forms an impurity energy level for trapping holes. For example, vanadium (V), ferrum (Fe), or ruthenium (Ru) can be used. The depth for introducing V, Fe, or Ru may be 70 nm or more and 100 nm or less.

Then, the mask film is removed, and after that, in isolation formation regions of the nitride semiconductor layer, for example, boron (B) is selectively ion-implanted and a transition metal is selectively introduced to form the isolation regions 20. As such, by introducing the transition metal into the isolation regions 20, it is possible to form the isolation regions 20, which are stable even after heat treatment such as ohmic sintering described below, and reliably traps electrons and holes to have high semi-insulating properties.

Next, by, for example, dry etching, formation regions of a source electrode and a drain electrode, which are located on the both sides of the p-type GaN layer 15 and in the highly resistive regions 15a, are selectively removed to expose the underlying AlGaN layer 14. Then, a resist pattern for covering upper surfaces of the p-type GaN layer 15 and the highly resistive regions 15a is formed, and a multilayer of Ti/Al is stacked by, for example, electron beam evaporation. Then, a so-called liftoff process for removing the resist pattern is performed, and further, given ohmic sintering heat treatment is performed to form the source electrode 17 and the drain electrode 18, each of which is made of Ti/Al. The depth for dry etching the highly resistive regions 15a is not limited to the depth for removing only the highly resistive regions 15a, but may be the depth reaching inside the AlGaN layer 14, or further, reaching the GaN layer 13.

Then, by, for example, electron beam evaporation and a liftoff process, the gate electrode 16 made of Pd is formed directly on the p-type GaN layer 15, into which no transition metal is introduced. Note that, the material for forming the gate electrode is not limited to Pd, but may be a metal such as nickel (Ni) or platinum (Pt), which has a high work function. Note that, the gate electrode 16 may be at least partially in contact with the p-type GaN layer 15, and the other parts may be in contact with the highly resistive regions 15a. In this case, an insulating film may be inserted between the upper surfaces of the highly resistive regions 15a and the gate electrode 16.

As described above, in the first embodiment, the highly resistive regions 15a are formed by introducing the transition metal into the regions on the both sides of the p-type GaN layer 15, on which the gate electrode 16 is formed, thereby determining the width of the p-type GaN layer 15. This reduces the width of the p-type GaN layer 15 for controlling a drain current.

Conventionally, regions on both sides of a gate electrode formation region in the p-type semiconductor layer are removed by, for example, dry etching to form a gate electrode thereon. This method has its limit to drastically reduce the width of the p-type semiconductor layer.

By contrast, in the first embodiment, the gate electrode 16 can be formed even if the p-type GaN layer 15 has a sufficiently small width, and thus, the p-type GaN layer 15 is easily made thinner. As a result, a normally-off type Group III nitride semiconductor HFET having excellent properties can be obtained.

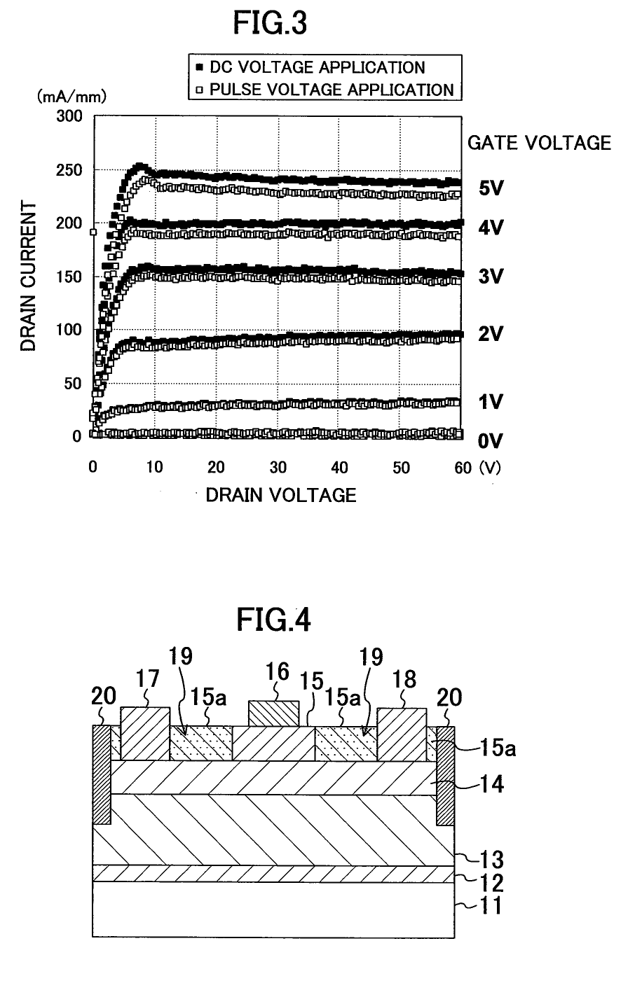

FIG. 3 illustrates static characteristics in the HFET according to the first embodiment, when a bias voltage is applied as a DC voltage, and when a bias voltage is applied as a pulse voltage (where a pulse width is 0.5 μs, and a pulse interval is 1 ms). The phrase “application of a pulse voltage” as used here means that a voltage is applied at the bias point, at which a transistor having a gate voltage of 0 V and a drain voltage of 60 V is off, to reach a given bias point where the pulse width is 0.5 μs and the pulse interval is 1 ms. As such, when the transistor is rapidly turned on from the off state with a pulse voltage, and when carriers are trapped by a surface level at the off state of the transistor, current collapse phenomenon occur, since the channel is depleted due to the trapped carriers.

However, in the first embodiment, as seen from FIG. 3, the values when a DC voltage is applied and the values when a pulse voltage is applied are substantially identical, and a collapse-free condition is created.

To be specific, in the first embodiment, instead of removing the regions of the p-type GaN layer 15 on both sides of the gate electrode 16, the transition metal (Ti), which forms an energy level for trapping holes, is introduced into the regions. This enables a selective increase in the resistance of the regions of the p-type GaN layer 15 on the both sides of the gate electrode 16 without affecting electrons, which are carriers. Therefore, a nitride semiconductor HFET, which is free from current collapse and of a normally-off type can be implemented.

Furthermore, not only by ion-implanting impurities such as boron (B) but also by introducing the transition metal into the isolation regions 20, it is possible to form the isolation regions 20, which are stable even after heat treatment, and traps both of electrons and holes, which are carriers, to have high semi-insulating properties.

### Modification of First Embodiment

The transition-metal-doped regions 19, into which the transition metal is introduced, does not necessarily reach the undoped AlGaN layer 14 and the underlying undoped GaN layer 13, and may be formed only in the p-type GaN layer 15 as in a modification shown in FIG. 4. In this modification, the depth for introducing Ti is 70 nm or more and 100 nm or less.

### Second Embodiment

A second embodiment of the present invention will be described hereinafter with reference to the drawings.

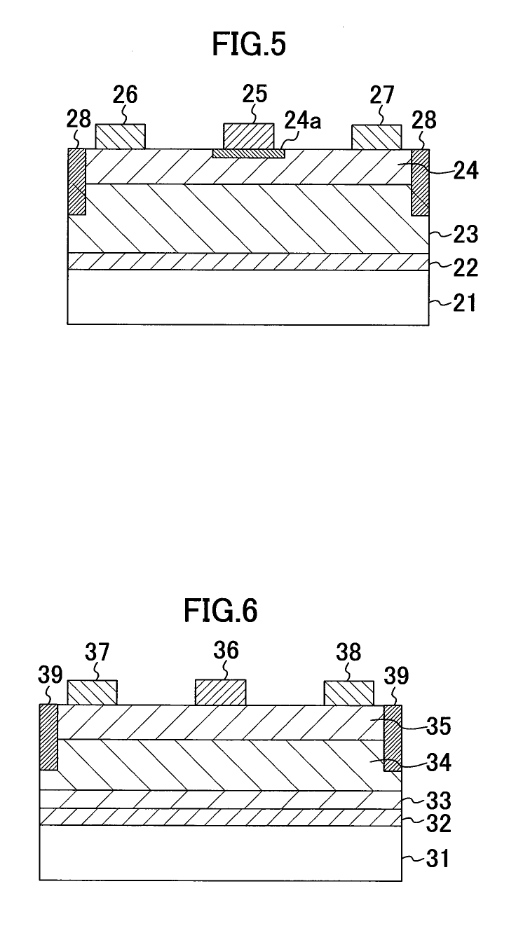

FIG. 5 illustrates a semiconductor device according to the second embodiment of the present invention, and a cross-sectional structure of a Heterojunction Field Effect Transistor (HFET) made of a Group III nitride semiconductor.

As shown in FIG. 5, in the HFET according to the second embodiment, on a main surface of a substrate 21 made of, for example, sapphire, a buffer layer 22 having thickness of 100 nm and made of aluminum nitride (AlN), an undoped GaN layer (a channel formation layer) 23 having thickness of 2 μm, and an undoped AlGaN layer (a carrier supply layer) 24 having thickness of 25 nm, are formed one on another by epitaxial growth.

In an upper portion of the AlGaN layer 24, a highly resistive region 24a is formed, into which a transition metal is selectively introduced, and on the highly resistive region 24a, a gate electrode 25 made of palladium (Pd) is formed in contact with the highly resistive region 24a.

In regions on the AlGaN layer 24, which are on both sides of the highly resistive region 24a, a source electrode 26 and a drain electrode 27, each of which is a multilayer of titanium (Ti) and aluminum (Al), are formed in contact with the AlGaN layer 24. Note that the source electrode 26 and the drain electrode 27 may be in contact with the AlGaN layer 24 only, with the underlying GaN layer 23 only, or with both of the GaN layer 23 and the AlGaN layer 24.

In regions outside the source electrode 26 and the drain electrode 27, isolation regions 28 are formed, into which boron (B) and a transition metal, e.g., titanium (Ti) or ruthenium (Ru), are introduced to increase the resistance.

As a feature of the second embodiment, the gate electrode 25 is formed on and in contact with the highly resistive region 24a formed by introducing the transition metal. This enables reduction in gate leakage current.

An example of manufacturing a Group III nitride semiconductor HFET having the above-described structure will be given below.

First, for example, by MOCVD, on the main surface of the substrate 21 made of sapphire, the buffer layer 22 having thickness of 100 nm and made of AlN, the undoped GaN layer 23 having thickness of 2 μm, and the undoped AlGaN layer 24 having thickness of 25 nm, are epitaxially grown one on another. The material of the substrate 21 is not limited to sapphire, and may be Si, SiC, GaN, or the like.

Next, on the epitaxially formed AlGaN layer 24, a mask film (not shown) is formed, which exposes a gate electrode formation region and is made of silicon oxide, for example. With the use of the formed mask film, a transition metal is selectively introduced into the AlGaN layer 24 to form the highly resistive region 24a. Since it is required that no current flows in the highly resistive region 24a formed by introducing the transition metal, both electrons and holes are desirably trapped by an energy level formed by introducing the transition metal. Thus, it is desirable to introduce a transition metal (such as Ru) which forms an energy level for trapping both of electrons and holes, or at least two types of transition metals: a transition metal (such as Cu) which forms an energy level for trapping electrons, and a transition metal (such as Ti) which forms an energy level for trapping holes. Out of the transition metals shown in FIGS. 2A and 2B, the transition metals having larger atomic weight are preferable, since they are hardly diffused into other sites after introduced into the nitride semiconductor layer to achieve high reliability. For example, ruthenium (Ru) having larger atomic weight is preferable. Moreover, when Ru is introduced into an interstitial site, the number of d-electrons, which do not chemically bond; is seven, the Ru concentration may be one-seventh or more of the concentration of holes in the AlGaN layer 24, for example, about 1×10²⁰ cm⁻³.

As a method of the Ru introduction, ion implantation, thermal diffusion, or the like can be used. In particular, thermal diffusion is preferable, since the nitride semiconductor layer is not damaged when Ru is introduced.

The depth for introducing the transition metal may be the depth not reaching the interface between the AlGaN layer 24 and the GaN layer 23, and is preferably 5 nm, for example.

Then, the mask film is removed, and after that, in isolation formation regions in the nitride semiconductor layer, for example, boron (B) is ion-implanted and a transition metal is introduced to form the isolation regions 28. As such, by introducing the transition metal into the isolation regions 28, it is possible to form the isolation regions 28, which are stable even after heat treatment such as ohmic sintering described below, and reliably trap electrons and holes to have high semi-insulating properties.

Next, a resist pattern for exposing formation regions of a source electrode and a drain electrode on the AlGaN layer 24 is formed, and a multilayer of Ti/Al is stacked by, for example, electron beam evaporation. Then, a so-called liftoff process for removing the resist pattern is performed, and further, given ohmic sintering heat treatment is performed to form the source electrode 26 and the drain electrode 27, each of which is made of Ti/Al.

Then, by, for example, electron beam evaporation and a liftoff process, the gate electrode 25 made of Pd is formed directly on the highly resistive region 24a. The material for forming the gate electrode is not limited to Pd, but may be a metal such as nickel (Ni) or platinum (Pt), which has a high work function.

As described above, in the second embodiment, into the formation region of the gate electrode 25 on the AlGaN layer 24, the transition metal is selectively introduced to form the highly resistive region 24a. Thus, since the gate electrode 25 is in contact with the highly resistive region 24a, a nitride semiconductor HFET having dramatically reduced gate leakage current can be easily obtained.

### Third Embodiment

A third embodiment of the present invention will be described hereinafter with reference to the drawings.

FIG. 6 illustrates a semiconductor device according to the third embodiment of the present invention, and a cross-sectional structure of a Heterojunction Field Effect Transistor (HFET) made of a Group III nitride semiconductor.

As shown in FIG. 6, in the HFET according to the third embodiment, on a main surface of a substrate 31 made of, for example, sapphire, a buffer layer 32 having thickness of 100 nm and made of aluminum nitride (AlN), a highly resistive layer 33 having has thickness of 500 nm and made of gallium nitride (GaN), into which a transition metal is introduced, an undoped GaN layer (a channel formation layer) 34 having thickness of 1 μm, and an undoped AlGaN layer (a carrier supply layer) 35 having thickness of 25 nm, are formed one on another by epitaxial growth.

On the AlGaN layer 35, a gate electrode 36 made of palladium (Pd) is formed in contact with the AlGaN layer 35.

In regions on the AlGaN layer 35, which are on both sides of the gate electrode 36, a source electrode 37 and a drain electrode 38, each of which is a multilayer of titanium (Ti) and aluminum (Al), are formed in contact with the AlGaN layer 35. Note that the source electrode 37 and the drain electrode 38 may be in contact with the AlGaN layer 35 only, with the underlying GaN layer 34 only, or with both of the GaN layer 34 and the AlGaN layer 35.

In regions outside the source electrode 37 and the drain electrode 38, isolation regions 39 are formed, into which boron (B) and a transition metal, e.g., titanium (Ti) or ruthenium (Ru), are introduced to increase the resistance.

As a feature of the third embodiment, the highly resistive layer 33 formed by introducing the transition metal is provided under the GaN layer 34. Thus, when a transistor is off, leakage current flowing through a lower region of the GaN layer 34 and the buffer layer 32 can be reduced.

An example of manufacturing a Group III nitride semiconductor HFET having the above-described structure will be given below.

First, for example, by MOCVD, on the main surface of the substrate 31 made of sapphire, the buffer layer 32 having thickness of 100 nm and made of AlN, the highly resistive layer 33 having thickness of 500 nm and made of GaN, into which a transition metal is introduced, the undoped GaN layer 34 having thickness of 1 μm, and the undoped AlGaN layer 35 having thickness of 25 nm, are epitaxially grown one on another. Note that, the thickness of the highly resistive layer 33 made of GaN and into which the transition metal is introduced is not limited to 500 nm and may be at least 5 nm or more. The material of the substrate 31 is not limited to sapphire, and may be Si, SiC, GaN, or the like.

The transition metal introduced into the highly resistive layer 33 is preferably a transition metal which forms an energy level for trapping electrons. The transition metal is not limited to one type, and two or more types of transition metals may be introduced. Out of the transition metals, transition metals having larger atomic weight are preferable, since they are hardly diffused into other sites after introduced into a nitride semiconductor layer to achieve high reliability. For example, ruthenium (Ru) is preferable, which has the same arrangement of d-electrons as ferrum (Fe) and has larger atomic weight. In this case, as the organometallic raw material of Ru, bis(dimethylcyclopentadienyl)ruthenium or diethylruthenocene are used. Moreover, when Ru is introduced into an interstitial site, the number of d-electrons, which do not chemically bond, is seven; the Ru concentration may be one-seventh or more of the concentration of carriers in the GaN layer, for example, about 1×10²⁰ cm⁻³.

Then, in isolation formation regions in the nitride semiconductor layer, for example, boron (B) is ion-implanted and a transition metal is introduced to form the isolation regions 39. As such, by introducing the transition metal into the isolation regions 39, it is possible to form the isolation regions 39, which are stable even after heat treatment such as ohmic sintering described below, and reliably trap electrons and holes to have high semi-insulating properties.

Next, a resist pattern for exposing formation regions of a source electrode and a drain electrode on the AlGaN layer 35 is formed, and a multilayer of Ti/Al is stacked by, for example, electron beam evaporation. Then, a so-called liftoff process for removing the resist pattern is performed, and further, given ohmic sintering heat treatment is performed to form the source electrode 37 and the drain electrode 38, each of which is made of Ti/Al.

Then, by using e.g., electron beam evaporation and a liftoff process, the gate electrode 36 made of Pd is formed directly on a region of the AlGaN layer 35 and between the source electrode 37 and the drain electrode 38. Note that, the material for forming the gate electrode is not limited to Pd, but may be a metal such as nickel (Ni) or platinum (Pt), which has a high work function.

As described above, in the third embodiment, by forming under the undoped GaN layer 34, the highly resistive layer 33, which is made of GaN, into which the transition metal is introduced, a nitride semiconductor HFET, which can reduce leakage current flowing under the GaN layer 33 or through the buffer layer 32 when the transistor is off.

### Fourth Embodiment

A fourth embodiment of the present invention will be described hereinafter with reference to the drawings.

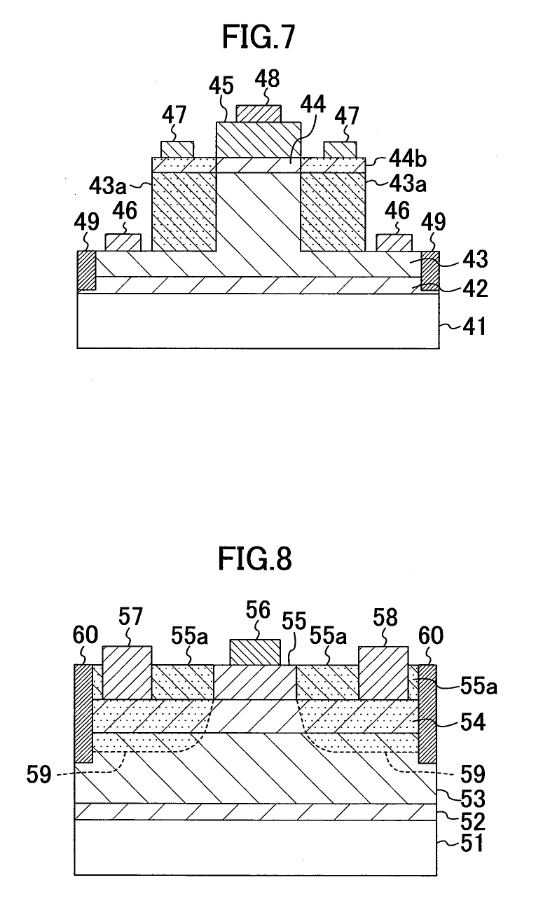

FIG. 7 illustrates a semiconductor device according to the fourth embodiment of the present invention, and a cross-sectional structure of a bipolar transistor made of a Group III nitride semiconductor.

As shown in FIG. 7, in the bipolar transistor according to the fourth embodiment, on a main surface of a substrate 41 made of, for example, sapphire, a buffer layer 42 having thickness of 100 nm and made of aluminum nitride (AlN), a collector layer 43 having thickness of 400 nm and made of p-type GaN doped with Mg, a base layer 44 having thickness of 100 nm and made of n-type GaN doped with Si, and an emitter layer 45 having thickness of 200 nm and made of p-type AlGaN doped with Mg are formed one on another by epitaxial growth.

An upper surface of a peripheral portion of the collector layer 43 is exposed after the base layer 44 and the emitter layer 45 are removed, and a collector electrode 46 made of Pd is formed on the exposed surface.

An upper surface of a peripheral portion of the base layer 44 is exposed after the emitter layer 45 is removed, and a base electrode 47 formed of a multilayer of Ti and Al is formed on the exposed surface. Furthermore, an emitter electrode 48 made of Pd is formed on the emitter layer 45.

A transition metal, e.g., titanium (Ti), which traps holes being majority carriers, is introduced into regions of the collector layer 43 and the base layer 44, which are under the emitter layer 45. As a result, the regions of the collector layer 43, into which the transition metal is introduced becomes highly resistive regions 43a, while the regions of the base layer 44, into which the transition metal is introduced becomes non-highly resistive regions 44b.

Furthermore, in regions of the collector layer 43 and the buffer layer 42 located outside the collector electrode 46, isolation regions 29 are formed, into which boron (B) and a transition metal, e.g., titanium (Ti) or ruthenium (Ru), are introduced to increase the resistance.

As a feature of the fourth embodiment, the transition metal for trapping holes is introduced into parts (peripheral portions) of the collector layer 43 and the base layer 44. Thus, only resistance of the regions of the collector layer 43, into which the transition metal is introduced, is increased to form the highly resistive regions 43a. This enables reduction in the base-collector junction area without raising the resistance of the base layer 44 itself to reduce base-collector capacitance.

The maximum oscillation frequency (fₘₐₓ) of a bipolar transistor is represented by the following [Formula 1].

$${f}_{max} = \sqrt{\frac{{f}_{T}}{8 π {R}_{B} {C}_{BC}}}$$

In the formula, f_{T} represents a cutoff frequency, R_{B} represents base resistance, and C_{BC} represents base-collector capacitance. As seen from [Formula 1], in order to increase the maximum oscillation frequency f_{T}, the base resistance R_{B} and the base-collector capacitance C_{BC} need to be reduced. In the fourth embodiment, since the base-collector capacitance C_{BC} can be reduced without rising the base resistance R_{B}, a nitride semiconductor bipolar transistor having excellent frequency properties can be obtained.

An example of manufacturing a nitride semiconductor transistor having the above-described structure will be given below.

First, for example, by MOCVD, on the main surface of the substrate 41 made of sapphire, the buffer layer 42 having thickness of 100 nm and made of AlN, the collector layer 43 having thickness of 400 nm and made of p-type GaN doped with Mg, the base layer 44 having thickness of 100 nm and made of n-type GaN doped with Si, the emitter layer 45 having thickness of 200 nm and made of p-type AlGaN doped with Mg are epitaxially grown one on another. The material of the substrate 41 is not limited to sapphire, and may be Si, SiC, GaN, or the like.

For the p-type AlGaN forming the emitter layer 45, p-type GaN doped with Mg can be used. However, it is preferably p-type AlGaN, in which the base layer 44 and the emitter layer 45 can form a heterojunction to reduce an electron current flowing from the base layer 44 to the emitter layer 45.

Next, on the emitter layer 45, a first mask film (not shown) covering an emitter electrode formation region is formed on the emitter electrode formation region. Then, with the use of the formed first mask film, the peripheral portion of the base layer 44 is exposed by, for example, dry etching. Then, with the emitter electrode formation region covered with the first mask film, the transition metal, Ti is introduced into the exposed base layer 44 and underlying collector layer 43.

As a method of the Ti introduction, ion implantation, thermal diffusion, or the like can be used. In particular, thermal diffusion is preferable, since the nitride semiconductor layer is not damaged when Ti is introduced. The depth for introducing Ti may be the depth reaching inside the collector layer 43, for example, the depth to which Ti is introduced 300 nm deep from an upper surface of the base layer 44. Moreover, when Ti is introduced into an interstitial site, the number of d-electrons, which do not chemically bond, is two; the Ti concentration may be half or more of the concentration of holes in the collector layer 43, for example, about 1×10²⁰ cm⁻³.

As described above, impurity energy levels formed by Ti introduced as a transition metal trap holes but hardly affect electrons. Thus, in the base layer 44 doped with Si, non-highly resistive regions 44b are formed, of which resistance is not increased. On the other hand, since Ti introduced into the collector layer 43 doped with Mg selectively trap holes, it is possible to form the highly resistive regions 43a having an increased resistance only in the portion into which Ti is introduced. Note that the transition metal introduced into the collector layer 43 to form the highly resistive regions 43a is not limited to Ti, and may be a transition metal such as vanadium (V), which forms an impurity energy level for trapping holes.

Then, after removing the first mask film, a second mask film is formed, which covers the emitter layer 45 and the base layer 44 at the periphery of the emitter layer 45. Then with the use of the second mask film, the collector layer 43, into which no transition metal is introduced, is exposed by, for example, dry etching.

Next, isolation formation regions in the collector layer 43 and the buffer layer 42, for example, boron (B) is ion-implanted and a transition metal is introduced to form isolation regions 49. As such, by introducing the transition metal into the isolation regions 49, it is possible to form the isolation regions 49, which are stable even after heat treatment such as ohmic sintering described below, and reliably trap electrons and holes to have high semi-insulating properties.

Then, by, for example, electron beam evaporation and a liftoff process, the collector electrode 46 made of Pd is formed on the exposed portion of the collector layer 43, the base electrode 47 made of Ti/Al is formed on the exposed non-highly resistive regions 44b of the base layer 44, and the emitter electrode 48 made of Pd is formed on the emitter layer 45. Note that, the materials for the electrodes are not limited to those described above, and may be materials which are in ohmic contact with the nitride semiconductor layer.

In the fourth embodiment, a bipolar transistor, in which a collector layer and an emitter layer are of p-type conductivity, and a base layer is of n-type conductivity, i.e., a so-called PNP-type transistor is described. However, the present invention is applicable to an NPN-type transistor in which layers have the opposite conductivity types.

In an NPN-type the transistor, the collector layer 43 may be made of n-type GaN doped with Si instead of p-type GaN, the base layer 44 may be made of p-type GaN doped with Mg instead of n-type GaN, and the emitter layer 45 may be made of n-type AlGaN doped with Si instead of p-type AlGaN. Furthermore, in this case, for example, copper (Cu) is introduced into the highly resistive regions 43a as a transition metal. As such, by selectively introducing Cu into the collector layer made of n-type GaN doped with Si, electrons are trapped by an energy level formed in a band gap of n-type GaN to form the highly resistive regions.

Moreover, in an NPN-type the transistor, each of the collector electrode 46 and the emitter electrode 48 may be formed of a multilayer of Ti/Al, and the base electrode 47 may be made of Pd.

As described above, a nitride semiconductor bipolar transistor can be manufactured.

As such, in the fourth embodiment, the highly resistive regions 43a are formed by selectively introducing a transition metal into a part of the collector layer 43 without raising the base resistance to reduce base-collector capacitance. Therefore, a bipolar transistor made of a Group III nitride semiconductor having excellent high frequency properties can be obtained.

### Fifth Embodiment

When a transition metal element is introduced into a Group III nitride semiconductor by thermal diffusion or the like, and when diffusion temperature is low, the transition metal element is more likely to be introduced into the crystal lattice than a Ga site. This is because energy barrier is higher where the Ga atom is removed from the site and a transition metal atom falls into the site instead of the Ga atom, than where the transition metal exists interstitially within the lattice structure.

However, when a transition metal element having a particularly small mass number is used, an interstitial type has a lower stability than a site substitution type and thus, affects for example, long-term reliability when operated at a high temperature. The first principles band calculation performed by the present inventors predicted these problems, and clarified that, with respect to titanium (Ti), the site substitution type is more energetically-favored than the interstitial type by about 5.2 eV. With respect to ferrum (Fe), the difference is as large as about 9.5 eV, and is considered as more unstable than Ti. Thus, a method of maintaining long-term reliability without sacrificing high resistibility due to the introduced interstitial type transition metal element is required. In the fifth embodiment, a method of maintaining long-term reliability will be described in detail.

FIG. 8 illustrates a semiconductor device according to the fifth embodiment of the present invention, and a cross-sectional structure of a Heterojunction Field Effect Transistor (HFET) made of a Group III nitride semiconductor.

As shown in FIG. 8, in the HFET according to the fifth embodiment, on a main surface of a substrate 51 made of, for example, sapphire, a buffer layer 52 having thickness of 100 nm and made of aluminum nitride (AlN), an undoped GaN layer (a channel formation layer) 53 having thickness of 2 μm, an undoped AlGaN layer (a carrier supply layer) 54 having thickness of 25 nm, and an undoped a GaN layer 55 having thickness of 100 nm and doped with fluorine (F) as impurities are formed one on another by epitaxial growth. The undoped GaN layer 55 may be a p-type GaN layer doped with Mg. The term “undoped” as used here means that a dopant providing a conductivity type is intentionally not introduced during a crystal growth.

On the GaN layer 55, a gate electrode 56 made of Pd is formed in contact with the GaN layer 55. In regions of the GaN layer 55 except for a part under the gate electrode 56, highly resistive regions 55a with increased resistance are formed by introducing a transition metal, Ti.

In regions on the AlGaN layer 54, which are on both sides of the GaN layer 55 and exposed from highly resistive regions 55a, a source electrode 57 and a drain electrode 58, each of which is a multilayer of Ti and Al, are formed in contact with the AlGaN layer 54. Note that the source electrode 57 and the drain electrode 58 may be in contact with the AlGaN layer 54 only, with the underlying GaN layer 53 only, or with both of the GaN layer 53 and the AlGaN layer 54.

Furthermore, in regions outside the source electrode 57 and the drain electrode 58, isolation regions 60 are formed, into which boron (B) and a transition metal, e.g., Ti or ruthenium Ru, are introduced to increase the resistance.

As a feature of the fifth embodiment, as shown in FIG. 8, Ti for forming the highly resistive regions 55a is introduced to reach the AlGaN layer 54 under the GaN layer 55 and further upper portions of the underlying GaN layer 53 to form transition-metal-doped regions 59. However, as will be described later, since Ti increases resistance of the nitride semiconductor layer only, into which fluorine is introduced, the highly resistive regions 55a are formed only in the GaN layer 55 in this embodiment.

From the first principles band calculation performed by the present inventors, it was found that interstitial fluorine introduced into a nitride semiconductor layer, i.e., the GaN layer 55, forms a deep trap level. This is because fluorine has large electronegativity, and in an electron excess state, interstitial fluorine is neutralized by receiving one electron of the host. On the other hand, the introduction of interstitial fluorine increases lattice constraint, and modulation of polarization due to a positional change of the atom at a periphery of the fluorine atom. However, it was found from the first principles band calculation that such modulation slightly affects a transistor element.

It is clear from a molecular dynamics calculation that, similar to interstitial transition metals, interstitial fluorine has lower thermal stability than a site substitution type. In particular, when the temperature exceeds about 1000 K, fluorine begins interstitial movement. If a nitrogen defect exists within the crystal, and fluorine thermally moving interstitially within the lattice structure enters the defect site of nitrogen, fluorine serves as a double donor. This may drastically change electric properties.

In the fifth embodiment, in the nitride semiconductor transistor provided with the nitride semiconductor layer (the GaN layer 55), into which fluorine is introduced, between the gate electrode 56 and a carrier supply layer (the AlGaN layer 54), a channel region, which is formed at a heterojunction interface of AlGaN/GaN directly under the gate electrode 56, has a higher energy level than the Fermi level. This enables depletion of the channel region located under the gate electrode 56. This allows the nitride semiconductor transistor according to this embodiment to perform a so-called normally-off operation, in which no drain current flows when no gate voltage is applied, without reducing the maximum drain current.

Furthermore, in the fifth embodiment, instead of performing dry etching to the regions on the both sides of the gate electrode 56 as conventionally done, a transition metal is introduced, which forms an energy level for trapping only holes. This forms the highly resistive regions 55a, which are parts of the GaN layer 55 of which resistance is selectively increased by introducing fluorine. This enables a switching operation without trapping electrons existing in the channel region, and achieves a normally-off type nitride semiconductor HFET, in which no current collapse occurs.

Moreover, as described above, when both of the interstitial fluorine and the interstitial transition metal are introduced, the both are bonded to each other to be stable within the GaN crystal. This is clear from a result of the first principles band calculation performed by the present inventors. The case where interstitial fluorine and interstitial titanium are adjacent to each other is more energetically favored by about 3.9 eV than where the two are apart from each other. It is found, as described above, that the bond is stabilized by about 9.1 eV by fluorine introduction along with the result that it is less energetically favored by 5.2 eV than where the interstitial titanium is in a Ga site. As a result, the interstitial elements are bonded to each other to further increase thermal stability and long-term reliability.

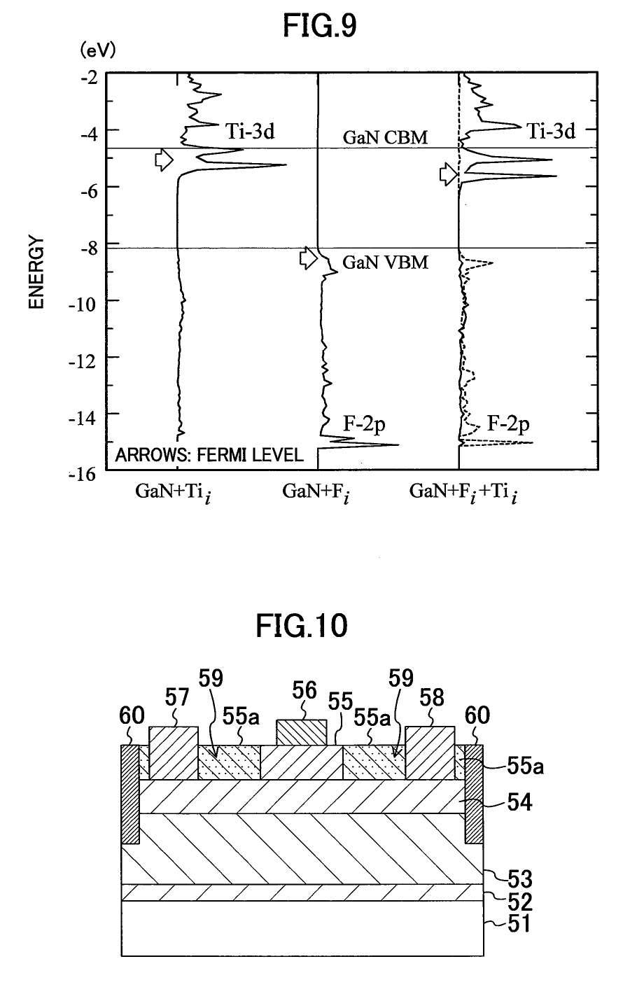

FIG. 9 illustrates differences between electron structures where interstitial fluorine and interstitial titanium exist in a GaN crystal and where they do not exist. FIG. 9 illustrates, from left to right, partial density of states where only interstitial Ti is introduced, where only interstitial fluorine is introduced, and where interstitial titanium and interstitial fluorine are adjacent to each other. Furthermore, the arrows in the drawing represent the Fermi levels. As seen from FIG. 9, where only interstitial titanium is introduced, as described above, an isolated level caused by d-electrons is formed in the band gap. Since the Fermi level exists around the isolated level, high insulating properties as described above are obtained.

On the other hand, interstitial fluorine forms, as described above, a deep trap level on a valence band side. The trap level exists at a lower energy position than the isolated level formed by interstitial Ti. This is the electronic state of the GaN layer 55, into which only fluorine is introduced. Note that, in the drawing, a 2p orbital of fluorine is shown as if it is bonded to the valence band, since the number of constituting atoms in a calculation model is small. This does not impair the advantages of the present invention.

Where both of fluorine and titanium are introduced, similar to the foregoing case, an isolated level caused by d-electrons of titanium is formed in the band gap, and it is found that the 2p orbital of fluorine exists on the valence band side. What is significantly different from where only fluorine is introduced is the location of the Fermi level. Similar to the case where only titanium is introduced, the Fermi level is at the same position as the isolated level caused by the d-electrons. However, the interstitial fluorine receives one electron from the interstitial Ti, the Fermi level slightly shifts to a lower energy side, than where only titanium is introduced. The interstitial fluorine and the interstitial Ti create in the host materials of GaN, a bonding state like an ionic bond. As a result, as described above, energy gain as high as about 9.1 eV can be obtained. That is, two interstitial atoms can be stabilized. This is the electron structure of the highly resistive regions 55a formed by introducing both of fluorine (F) and titanium (Ti) into the undoped GaN layer 55.

As such, even where both of the transition metal and fluorine are introduced into the Group III nitride semiconductor, an increase in resistance can be obtained due to a slight change of the Fermi level. Therefore, as described above, by arranging the interstitial elements of both of the transition metal and fluorine to be adjacent to each other, thermal stability and long-term reliability of the highly resistive regions 55a can be achieved.

An example of manufacturing a Group III nitride semiconductor HFET having the above-described structure will be given below.

First, for example, by MOCVD, on the main surface of the substrate 51 made of sapphire, the buffer layer 52 having thickness of 100 nm and made of AlN, the undoped GaN layer 53 having thickness of 2 μm, the undoped AlGaN layer 14 having thickness of 25 nm, and the undoped GaN layer 55 having thickness of 100 nm are epitaxially grown one on another. The material of the substrate 51 is not limited to sapphire, and may be Si, SiC, GaN, or the like. Furthermore, instead of the undoped GaN layer 55, undoped AlGaN can be used.

Next, in a gate electrode formation region on the epitaxially formed GaN layer 55, a mask film (not shown) is formed, which covers the electrode formation region and is made of, for example, silicon oxide. With the use of the formed mask film, Ti is selectively introduced into the GaN layer 55. As a method of the Ti introduction, ion implantation, thermal diffusion, or the like can be used. In particular, thermal diffusion is preferable, since the nitride semiconductor layer is not damaged when Ti is introduced. The depth for introducing Ti into the nitride semiconductor layer may be the depth, at which all the regions of the GaN layer 55 except for the region covered with the mask film become substantially the highly resistive regions 55a. Furthermore, as shown by the transition-metal-doped regions 59, the depth may reach the AlGaN layer 54 under the p-type GaN layer 55 or the GaN layer 53. For example, depth for introducing Ti may be 70 nm or more and 150 nm or less. The introduced Ti concentration may be for example, about 1×10¹⁷ cm⁻³ or more, more preferably 1×10²⁰ cm⁻³. Note that the transition metal introduced into the highly resistive regions 55a is not limited to Ti. Instead, Fe, Ru, or the like can be used. In this case, the depth for introducing Fe, or Ru may be 70 nm or more and 100 nm or less. With the use of these transition metals, the isolated level caused by d-electrons is lowered to a periphery of a center of the band gap, thereby obtaining high insulating properties.

Then, the mask film is removed, and after that, in isolation formation regions of the nitride semiconductor layer, for example, boron (B) is selectively ion-implanted and a transition metal is selectively introduced to form the isolation regions 60. As such, by introducing the transition metal into the isolation regions 60, it is possible to form the isolation regions 60, which are stable even after heat treatment such as ohmic sintering described below, and reliably traps electrons and holes to have high semi-insulating properties.

Next, by, for example, dry etching, the formation regions of a source electrode and a drain electrode, which are located on the both sides of the GaN layer 55 and in the highly resistive regions 55a, are selectively removed to expose the underlying AlGaN layer 54. Then, a resist pattern for covering upper surfaces of the GaN layer 55 and the highly resistive regions 55a is formed, and a multilayer of Ti/Al is stacked by, for example, electron beam evaporation. Then, a so-called liftoff process for removing the resist pattern is performed, and further, given ohmic sintering heat treatment is performed to form the source electrode 57 and the drain electrode 58, each of which is made of Ti/Al. Note that, the depth for dry etching the highly resistive regions 55a is not limited to the depth for removing only the highly resistive regions 55a, but may be the depth reaching inside the AlGaN layer 54, or further, reaching the GaN layer 53.

Then, the substrate 51 including the nitride semiconductor layer provided with the source electrode 57 and the drain electrode 58 is put into a chamber, into which fluorine series gas is introduced. Into the entire surface of the undoped GaN layer 55, fluorine is introduced by, for example, plasma treatment. The depth for introducing fluorine into the nitride semiconductor layer is substantially equal to the thickness of the GaN layer 55, for example, 100 nm. Since in Ti, the number of d-electrons, which do not chemically bond, is two; the concentration of fluorine may be twice or less of the Ti concentration, for example, about 5×10¹⁹ cm⁻³, when there are no carriers caused by other elements than fluorine. When other than fluorine, for example, magnesium (Mg), which is a dopant providing p-type conductivity is added, the carrier concentration of fluorine and Mg may be twice or less of the Ti concentration since holes caused by a Mg accepter also exist. When the transition metal is Fe instead of Ti, since the d-electrons of Fe, which do not chemically bond, is six; the concentration of fluorine may be six times or less of the Fe concentration when there are no carriers caused by other elements than fluorine. At this time, the process temperature is preferably a room temperature, or 500° C. or less. This distributes fluorine preferentially to interstitial positions within the lattice structure. The gate electrode formation region, which is obtained thereby in the undoped GaN layer 55 and into which fluorine is introduced, has p-type conductivity, as described above. On the other hand, the highly resistive regions 55a, into which both of Ti and fluorine are introduced, have high resistance, as described above. As such, when in the highly resistive regions 55a, Ti and fluorine are adjacent to each other, high thermal stability and high long-term reliability can be achieved.

Then, by, for example, electron beam evaporation and a liftoff process, the gate electrode 56 made of Pd is formed directly on the gate electrode formation region on the GaN layer 55, into which only fluorine is introduced. The material for forming the gate electrode is not limited to Pd, but may be a metal such Ni or Pt, which has a high work function. Note that, the gate electrode 56 may be at least partially in contact with the GaN layer 55, and the other parts may be in contact with the highly resistive regions 55a. In this case, an insulating film may be inserted between the upper surfaces of the highly resistive regions 55a and the gate electrode 56.

Furthermore, in the fifth embodiment, fluorine is introduced by plasma treatment, but may be by thermal diffusion using nitrogen trifluoride gas. To be specific, when fluorine is exposed for 10 minutes under the condition where a substrate temperature is 320° C., nitrogen gas is 11/min (at 0° C., 1 atmosphere), and nitrogen trifluoride gas is 10 ml/min (at 0° C., 1 atmosphere), fluorine of about 10²⁰ cm³ can be introduced into an interstitial site. In this case, the surface is less damaged than in plasma treatment. This leads to a further decrease in the trap level.

As described above, a normally-off type nitride semiconductor HFET can be obtained.

### Modification of Fifth Embodiment

The transition-metal-doped regions 59, into which the transition metal is introduced, does not necessarily reach the undoped AlGaN layer 54 and the underlying undoped GaN layer 53, and may be formed only in the GaN layer 55 doped with fluorine as in a modification shown in FIG. 10. In this modification, the depth for introducing Ti is 70 nm or more and 100 nm or less.

### INDUSTRIAL APPLICABILITY

In the semiconductor device according to the present invention, a highly resistive region being stable to withstand high-temperature heat treatment can be formed, and resistance of only one of an n-type semiconductor layer and a p-type semiconductor layer can be selectively increased. Thus, a normally-off type nitride semiconductor device, in which no current collapse occurs, and a nitride semiconductor device having a high maximum oscillation frequency can be obtained. Therefore, the present invention is useful for an increase in performance of power devices, high frequency devices, or the like.

1. A semiconductor device comprising:
a first semiconductor layer made of a first nitride semiconductor; and
a second semiconductor layer made of a second nitride semiconductor; wherein
the first semiconductor layer includes a first region, into which a transition metal is introduced,
the second semiconductor layer includes a second region, into which the transition metal is introduced, and
resistance of only one of the first region and the second region is increased.

2. The semiconductor device of claim 1, wherein
the first semiconductor layer except for the first region has n-type conductivity, and
electrons are trapped by an energy level, which is formed in a band gap of the first nitride semiconductor by the transition metal, thereby increasing resistance of the first region.

3. The semiconductor device of claim 1, wherein
the first semiconductor layer except for the first region has p-type conductivity, and
holes are trapped by an energy level, which is formed in a band gap of the first nitride semiconductor by the transition metal, thereby increasing resistance of the first region.

4. The semiconductor device of claim 2, wherein the transition metal is copper.

5. The semiconductor device of claim 2, wherein the transition metal is ruthenium.

6. The semiconductor device of claim 3, wherein the transition metal is titanium.

7. The semiconductor device of claim 3, wherein the transition metal is ruthenium.

8. A semiconductor device comprising:
a substrate;
a nitride semiconductor layer provided on the substrate;
a source electrode and a drain electrode electrically coupled to the nitride semiconductor layer; and
a gate electrode provided on the nitride semiconductor layer to be positioned between the source electrode and the drain electrode, wherein
the nitride semiconductor layer includes a highly resistive region, into which a transition metal is introduced.

9. The semiconductor device of claim 8, wherein
the nitride semiconductor layer includes a nitride semiconductor layer doped with impurities providing p-type conductivity, and
the highly resistive region is formed to exclude at least a part directly under the gate electrode in the nitride semiconductor layer, into which the impurities providing p-type conductivity are introduced.

10. The semiconductor device of claim 8, wherein the highly resistive region is formed under the gate electrode in the nitride semiconductor layer to be in contact with the gate electrode.

11. The semiconductor device of claim 8, wherein
the nitride semiconductor layer includes a channel region which is a channel of a current flowing between the source electrode and the drain electrode, and
the highly resistive region is formed under the channel region.

12. The semiconductor device of claim 8, wherein the highly resistive region is an isolation region located at a periphery of an active region of the semiconductor device.

13. A semiconductor device comprising:
a substrate;
a first nitride semiconductor layer provided on the substrate, and into which impurities providing a first conductivity type are introduced;
a second nitride semiconductor layer provided on and in contact with an upper surface of the first nitride semiconductor layer, and into which impurities providing a second conductivity type are introduced;
a third nitride semiconductor layer provided on and in contact with an upper surface of the second nitride semiconductor layer, and into which impurities providing the first conductivity type are introduced;
a collector electrode electrically coupled to the first nitride semiconductor layer;
a base electrode electrically coupled to the second nitride semiconductor layer; and
an emitter electrode electrically coupled to the third nitride semiconductor layer, wherein
the first nitride semiconductor layer includes a highly resistive region, into which a transition metal is introduced.

14. The semiconductor device of claim 13, wherein the highly resistive region is an isolation region located at a periphery of an active region of the semiconductor device.

15. A semiconductor device comprising:
a nitride semiconductor layer; and
a highly resistive region formed in the nitride semiconductor layer; wherein
into the highly resistive region, a transition metal and another element as impurities are introduced.

16. A semiconductor device comprising:
a nitride semiconductor layer; and
a highly resistive region formed in the nitride semiconductor layer, and into which a transition metal is introduced, wherein
at least one of the highly resistive region and a region adjacent to the highly resistive region includes fluorine interstitial in a lattice structure.
